(19) United States
(12) Patent Application Publication
(10) Pub. No.: US 2016/0359114 A1
(43) Pub. Date: Dec. 8, 2016

(54) METHOD FOR MANUFACTURING TRANSISTOR

(71) Applicant: FUJIFILM CORPORATION, Tokyo (JP)

(72) Inventor: Seigo NAKAMURA, Kanagawa (JP)

(73) Assignee: FUJIFILM CORPORATION, Tokyo (JP)

(21) Appl. No.: 15/244,398

(22) Filed: Aug. 23, 2016

Related U.S. Application Data
(63) Continuation of application No. PCT/JP2015/055806, filed on Feb. 27, 2015.

(30) Foreign Application Priority Data
Mar. 7, 2014 (JP) 2014-045244

(51) Int. Cl. H01L 51/00; H01L 51/05

(52) U.S. Cl. CPC H01L 51/0012; H01L 51/0566; H01L 51/0019; H01L 51/0018

(57) ABSTRACT

In the manufacturing of transistors, a film substrate on which three or more alignment marks are formed is used, the alignment marks are detected, and a treatment for controlling the expansion and shrinkage of the substrate is carried out once or more by means of at least one of a temperature control of the substrate and a humidity control of the substrate depending on detection results thereof. Therefore, in the manufacturing of transistors in which films are used as substrates, it is possible to form constituent members of transistors such as source electrodes or drain electrodes without pattern deviation regardless of the expansion and shrinkage of substrates attributed to environmental changes.

### CROSS-REFERENCE TO RELATED APPLICATIONS

This application is a Continuation of PCT International Application No. PCT/JP2015/055806 filed on Feb. 27, 2015, which claims priority under 35 U.S.C. §119(a) to Japanese Patent Application No. 2014-045244 filed on Mar. 7, 2014. The above application is hereby expressly incorporated by reference, in its entirety, into the present application.

### BACKGROUND OF THE INVENTION

1. Field of the Invention

The present invention relates to a method for manufacturing a transistor in which films such as plastic films are used as substrates. Specifically, the present invention relates to a method for manufacturing a transistor in which source electrodes, drain electrodes, and the like can be formed without causing pattern deviation.

2. Description of the Related Art

Film substrates such as plastic films are used in devices and the like in which logic circuits such as thin film transistors (TFTs), RF tags (RFIDs), or memories, which are used in liquid crystal displays or organic EL displays, are used because it is possible to reduce thicknesses, make devices flexible, and the like.

Transistors such as TFTs have fine structures obtained by forming fine electrodes and the like. Therefore, in the manufacturing of transistors, it is necessary to form patterns for electrodes and the like with an accuracy of a micrometer order.

As well known, in the manufacturing of transistors, there are a number of steps in which heating, application of solutions, or the like are carried out. However, compared with glass and the like which have thus far been used as substrates, films, such as plastic films, significantly expand and shrink due to temperature or humidity.

Therefore, in a case in which films are used as substrates, the expansion and shrinkage of substrates cause pattern deviation (positional deviation) against members constituting transistors, and it is not possible to stably manufacture appropriate transistors.

As methods for forming appropriate fine patterns without causing pattern deviation regardless of the above-described expansion and shrinkage (distortion) of substrates, methods in which alignment marks are used as described in JP2007-110048A and WO2009/130791A are known.

In these methods, alignment marks which serve as marks for position alignment are formed at the four corners and the like of substrate surfaces. After that, prior to the formation of patterns for electrodes and the like, the positions of the alignment marks are detected. Meanwhile, in the formation of patterns, pattern exposure is also included.

It is needless to say that the positions of alignment marks formed on substrates are already known. Therefore, from the difference between the positions of or intervals between the detected alignment marks and the formation positions of or intervals between the original alignment marks, the positional deviation of the alignment marks, that is, the expansion and shrinkage of the substrates can be detected. Therefore, patterns are reset (recalculated) depending on the detection results of the alignment marks so as to form patterns at appropriate positions with respect to the alignment marks, and patterns are formed in accordance with the reset patterns by means of, for example, inkjet printing, laser beam exposure, or the like, whereby transistors including no pattern deviation can be produced.

### SUMMARY OF THE INVENTION

When alignment marks are used, it is possible to manufacture transistors having, for example, appropriate source electrodes and drain electrodes, positional relationships with source electrodes, and the like by removing pattern deviation against individual members constituting transistors.

However, in the methods of the related art in which alignment marks are used, it is necessary to reset the positions of individual patterns depending on the detection results of alignment marks, and thus the manufacturing costs of transistors increase.

In addition, in the manufacturing of transistors using photography, patterns are formed by means of exposure in which photo masks are used. However, the methods in which the positions of patterns to be formed are reset depending on the detection results of alignment marks cannot be used in methods in which photo masks are used. Alternatively, in order to use the methods in which the positions of patterns to be formed are reset depending on the detection results of alignment marks in methods in which photo masks are used, it is necessary to prepare a number of kinds of photo mask for a single pattern.

An object of the present invention is to solve the above-described problem of the related art and to provide a method for manufacturing a transistor in which, in the manufacturing of transistors in which films are used as substrates, alignment marks are used, whereby pattern deviation against individual constituent members is not caused, and transistors having an appropriate positional relationship can be manufactured, furthermore, it is not necessary to reset patterns depending on the detection results of alignment marks, and photo masks can be used.

In order to achieve the above-described object, a method for manufacturing a transistor of the present invention provides a method for manufacturing a transistor in which a film is used as a substrate, the method comprising: using a substrate on which three or more alignment marks are formed; and detecting the alignment marks and carrying out an expansion and shrinkage control treatment for controlling expansion and shrinkage of the substrate once or more by means of at least one of a temperature control of the substrate and a humidity control of the substrate depending on detection results of the alignment marks.

In the above-described method for manufacturing a transistor of the present invention, it is preferable that the manufacturing of the transistor includes at least a step of forming a gate electrode, a step of forming a gate insulating film, a step of forming a semiconductor layer, and a step of forming a source electrode and a drain electrode, and the expansion and shrinkage control treatment is carried out in the middle of or prior to at least one of the step of forming a gate electrode, the step of forming a gate insulating film, the step of forming a semiconductor layer, and the step of forming a source electrode and a drain electrode.

In addition, it is preferable that a degree of deviation of the alignment marks is detected from the detection results of the alignment marks, and at least one of the temperature control of the substrate and the humidity control of the substrate is carried out on the basis of the degree of deviation of the alignment marks and at least one of a linear expansion coefficient and a hygroscopic expansion coefficient of the substrate.

In addition, it is preferable that the transistor is manufactured by fixing the substrate to a carrier, at least one of the linear expansion coefficient and hygroscopic expansion coefficient of the substrate is ascertained in a state in which the substrate is fixed to the carrier, and at least one of the temperature control of the substrate and the humidity control of the substrate is carried out using the ascertained information.

In addition, it is preferable that, in a state in which at least one of the temperature and humidity of the substrate obtained by the expansion and shrinkage control treatment is maintained, pattern exposure in which a printing method or a photo mask is used is carried out, thereby carrying out pattern formation in the manufacturing of the transistor.

In addition, it is preferable that the expansion and shrinkage control treatment is a humidity control, and the expansion and shrinkage control treatment is carried out by blowing gas having a controlled humidity toward the substrate.

In addition, it is preferable that the alignment marks are detected while transporting a long substrate in a longitudinal direction, the expansion and shrinkage control treatment is carried out on the downstream side of a detection position of the alignment marks, and pattern formation is carried out on the downstream side of the expansion and shrinkage control treatment in the manufacturing of the transistor.

In addition, it is preferable that the substrate is a gas barrier film obtained by forming a gas barrier membrane on a support, and the gas barrier membrane is obtained by alternately laminating one or more of organic layers and inorganic layers.

In addition, it is preferable that the inorganic layer is a silicon nitride film.

In addition, it is preferable to further comprise a step of forming an organic semiconductor layer.

In addition, it is preferable that a heat treatment of the substrate is carried out prior to the expansion and shrinkage control treatment carried out for the first time.

Furthermore, it is preferable that a step of forming the alignment marks is included, and the alignment marks are formed when patterning for a lowermost layer is carried out in the manufacturing of the transistor.

According to the above-described present invention, electrodes and the like can be formed by restoring the positions of alignment marks, that is, the expansion and shrinkage of a substrate to the original state by means of a temperature control, humidity control, or the like of the substrate depending on the detection results of the alignment marks formed on the substrate.

Therefore, according to the manufacturing method of the present invention, it is possible to stably manufacture appropriate transistors including no pattern deviation against electrodes, wires, and the like. Furthermore, since it is not necessary to reset (recalculate) patterns depending on the detection results of alignment marks, it is possible to reduce the manufacturing costs of transistors. Furthermore, according to the manufacturing method of the present invention, it is also possible to deal with methods in which photo masks are used with a single photo mask.

### BRIEF DESCRIPTION OF THE DRAWINGS

FIGS. 1A to 1D are conceptual diagrams for describing an example of a method for manufacturing a transistor of the present invention.

FIGS. 2E to 2G are conceptual diagrams for describing an example of the method for manufacturing a transistor of the present invention.

FIG. 3A is a conceptual diagram of an example in which the method for manufacturing a transistor of the present invention is used in a roll to roll-type manufacturing device, and FIG. 3B is a conceptual diagram of an example of a substrate which is used in the manufacturing device illustrated in FIG. 3A.

### DESCRIPTION OF THE PREFERRED EMBODIMENTS

Hereinafter, a method for manufacturing a transistor of the present invention will be described in detail on the basis of a preferred example illustrated in the accompanying drawings.

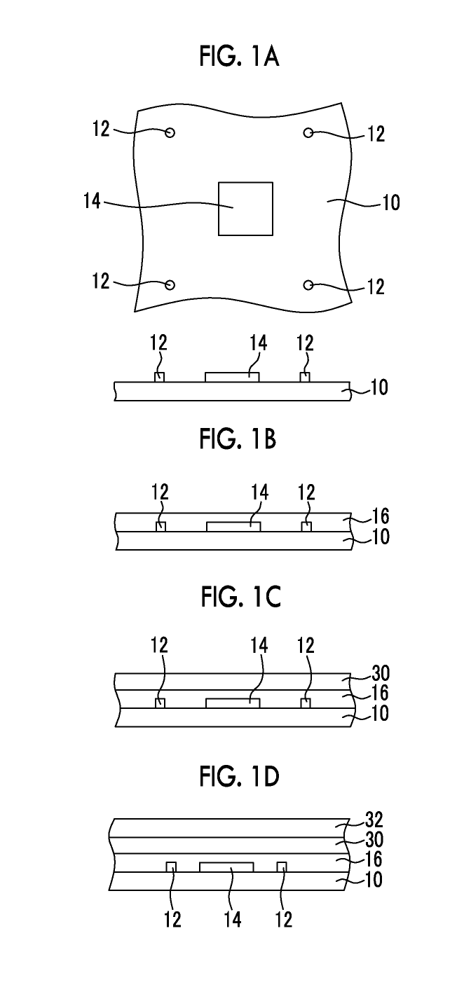

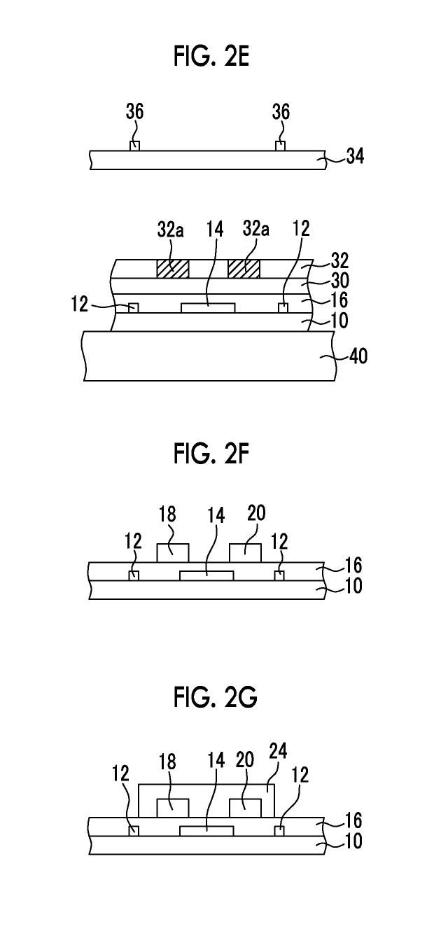

FIGS. 1A to 2G schematically illustrate an example of the method for manufacturing a transistor of the present invention.

In the method for manufacturing a transistor of the present invention, transistors are formed using a film substrate 10 on which three or more alignment marks are formed.

An example illustrated in FIGS. 1A to 2G is an example in which, as an example, the method for manufacturing a transistor of the present invention is used to manufacture a bottom gate-bottom contact-type transistor in which a gate electrode 14 is formed on the film substrate 10 on which alignment marks 12 are formed, a gate insulating film 16 is formed so as to cover the gate electrode 14, a source electrode 18 and a drain electrode 20 are formed on the gate insulating film 16, and a semiconductor layer 24 is formed on the gate insulating film 16 and the source electrode 18 and the drain electrode 20.

However, the present invention is not limited thereto and can be used to manufacture a variety of well-known transistors such as top gate-bottom contact-type transistors, bottom gate-top contact-type transistors, and top gate-bottom contact-type transistors.

In the method for manufacturing a transistor of the present invention, as the film substrate 10, it is possible to use films (film-like articles) consisting of a variety of materials which are used for substrates in so-called thin film transistors such as metal such as silicon, ceramics, glass, and plastic. In the following description, the method for manufacturing a transistor of the present invention will also be simply referred to as “the manufacturing method of the present invention”. In addition, in the following description, the film substrate 10 will also be simply referred to as “the substrate 10”.

Among these, from the viewpoint of costs, flexibility, weight reduction, cracking resistance, insulating properties, and the like, plastic films (resin films) are preferably used as the substrate 10.

Examples of materials forming the plastic films include thermoplastic resins such as polyester resins, methacrylic resins, methacrylic acid-maleic acid copolymers, polystyrene resins, fluorine resins, polyimides, fluorinated polyimide resins, polyamide resins, polyamideimde resins, polyetherimide resins, cellulose acylate resins, polyurethane resins, polyether ether ketone resins, polycarbonate resins, alicyclic polyolefin resins, polyarylate resins, polyethersulfone resins, polysulfone resins, cycloolefin copolymers, fluorene ring-modified polycarbonate resins, alicyclic modified polycarbonate resins, fluorene ring-modified polyester resins, and acryloyl compounds and the like.

Among these, gas barrier films obtained by forming a gas barrier membrane on the surface of the above-described plastic film as a support are preferably used as the substrate 10.

Among these, particularly, organic-inorganic lamination-type gas barrier films obtained by using the above-described plastic film as a support and alternately forming organic layers consisting of acrylic resins or methacrylic resins and inorganic layers consisting of silicon oxide, silicon nitride, or the like as a gas barrier membrane on the surface of the plastic film are particularly preferably used as the substrate 10.

In a case in which organic-inorganic lamination-type gas barrier films are used as the substrate 10, a variety of materials can be used as materials forming the organic layers and the inorganic layers. Here, inorganic layers are generally weak with respect to expansion and shrinkage, and there are cases in which cracks are generated due to expansion and shrinkage. When cracks are generated in inorganic layers, gas barrier performance deteriorates. Therefore, inorganic layers are preferably silicon nitride films and particularly preferably silicon nitride films formed using CVD. Silicon nitride films formed using CVD include hydrogen atoms in the films and are thus considered to be capable of obtaining strong expansion and shrinkage properties due to hydrogen bonds.

Meanwhile, in a case in which organic-inorganic lamination-type gas barrier films are used as the substrate 10, lowermost layers may be organic layers or inorganic layers. In addition, uppermost layers may also be organic layers or inorganic layers. Furthermore, regarding the numbers of the organic layers and the inorganic layers being laminated, a single organic layer and a single inorganic layer may be laminated together, or multiple organic layers and multiple inorganic layers may be alternately laminated together, and the numbers of the organic layers and the inorganic layers may be different from each other.

The lowermost layer of the gas barrier film refers to a layer formed on the surface of the support. The uppermost layer of the gas barrier film refers to a layer formed on the surface of the gas barrier film opposite to the support.

In a case in which a gas barrier film is used as the substrate 10, generally, a transistor is preferably formed on a gas barrier membrane. That is, in a case in which an organic-inorganic lamination-type gas barrier film is used as the substrate 10, a transistor is preferably formed on the surface of an organic layer or an inorganic layer.

In a case in which a gas barrier film is used as the substrate 10, when the support is provided inside the gas barrier membrane with respect to the transistor, there is a possibility that the transistor is adversely affected by moisture in the support or temporal changes of the support. In contrary, when a transistor is formed on the gas barrier membrane, the above-described disadvantage can be avoided.

In the manufacturing method of the present invention, prior to the manufacturing of transistors, it is preferable to carry out a heat treatment on the substrate 10.

Plastic films are generally manufactured by means of stretching. At this time, there are many cases in which the degrees of drawing differ in the MD direction and the TD direction. Therefore, in many cases, the thermal shrinkage ratios of plastic films differ in the MD direction and the TD direction. The MD direction refers to a transportation direction of films in the manufacturing of plastic, and the TD direction refers to a direction orthogonal to the MD direction, that is, the transportation direction of films.

While described below, in the manufacturing method of the present invention, as a preferred embodiment, an expansion and shrinkage control treatment for controlling the expansion and shrinkage of the substrate 10 is carried out by means of the temperature control or humidity control of the substrate 10. The expansion and shrinkage control treatment refers to, in other words, a treatment for improving the positional deviation of alignment marks.

However, when the thermal shrinkage ratio differs in the MD direction and in the TD direction, it is not possible to appropriately carry out the expansion and shrinkage control treatment by means of temperature controls or humidity controls.

Therefore, in the manufacturing method of the present invention, it is preferable to carry out heat treatments (thermal shrinkage elimination/thermal relaxation treatments) for removing the thermal shrinkage of the substrate 10, that is, the plastic film in the MD direction and the TD direction as necessary prior to the manufacturing of transistors.

The thermal treatments may be carried out using well-known methods such as heating using heaters, heating using constant-temperature tanks, and heating using hot air.

In addition, as the conditions of the thermal treatments such as temperatures, durations, and the like of the thermal treatments, conditions under which shrinkage in the MD direction and the TD direction can be removed throughout manufacturing processes of transistors may be appropriately set depending on the forming materials, thicknesses, or the like of the substrate 10 being used. As an example, conditions under which the thermal treatments are carried out at a temperature that is equal to or higher than the peak temperature in manufacturing processes of transistors are exemplified.

In the manufacturing method of the present invention, transistors are manufactured on the above-described substrate 10.

Here, a transistor described below may be manufactured using only the substrate 10. However, depending on the forming materials, thicknesses, or the like of the substrate 10, there are cases in which, with the substrate 10 alone, stiffness is weak and the shape of the substrate 10 becomes unstable.

Therefore, it is preferable to manufacture transistors after attaching carrier substrates such as glass plates to the rear surface (the surface on which no transistors are formed) of the substrate 10. In such a case, it is possible to form a gate electrode 14 described below or the like in a state in which the shape of the substrate 10 is appropriately maintained.

Carrier substrates may be attached to the substrate 10 using well-known methods in which carrier films (films having re-peeling performance) or the like are used.

In the example illustrated in the drawings, as schematically illustrated in FIG. 1A, first, patterns for the gate electrode 14 are formed on the surface of the substrate 10.

As the forming materials of the gate electrode 14, it is possible to use a variety of well-known materials that are used as gate electrodes in thin film transistors. Examples thereof include metals such as aluminum, chromium, copper, molybdenum, tungsten, gold, and silver, alloys, transparent conductive oxides (TCOs) such as indium tin oxide (ITO), conductive polymers such as polyethylenedioxythiophene-polystyrenesulfonate (PEDOT-PSS), laminate structures thereof, and the like.

In addition, as the methods for forming the gate electrode 14, it is also possible to use a variety of well-known methods in accordance with the forming materials.

Example thereof include methods in which sputtering or gas-phase film formation methods (gas-phase deposition methods) such as vacuum vapor deposition and photolithography are used, methods in which gas-phase film formation methods and shadow masks are used, methods in which printing such as inkjet printing is carried out, and the like. Shadow masks refer to masks for covering portions in which films are not formed (non-film-formation portions).

Here, in the example illustrated in the drawings, as a preferred embodiment, during the formation of the gate electrode 14, that is, the formation of patterns for the lowermost layer, alignment marks 12 are formed together with the gate electrode 14. Therefore, in this case, the gate electrode 14 and the alignment marks 12 are formed of the same method at the same time. Meanwhile, depending on the patterns formed for the gate electrode 14, it is also possible to use the gate electrode 14 as alignment marks.

In such a case, it is possible to produce the gate electrode 14 (patterns for the lowermost layer) in an appropriate positional relationship with the alignment marks without detecting the alignment marks. In addition, since alignment marks can be formed together with the gate electrode 14 at the same time, compared with a case in which alignment marks are separately formed, it is possible to reduce the number of steps, which is also preferable.

However, the manufacturing method of the present invention is not limited thereto, and it is also possible to form alignment marks first and then form the gate electrode 14.

In this case, the gate electrode 14 and the alignment marks 12 may be formed of the same material or formed of different materials. In addition, the methods for forming the gate electrode 14 and the alignment marks 12 may be different from each other.

Meanwhile, in a case in which the alignment marks 12 are not formed at the same time as the gate electrode 14, as the forming materials of the alignment marks, it is possible to use a variety of well-known materials that are used as alignment marks in thin film transistors.

Specifically, in addition to the above-described forming materials of the gate electrode 14, examples thereof include ink including a variety of dyes or pigments.

In addition, in a case in which the alignment marks 12 are not formed at the same time as the gate electrode 14, as the methods for forming the alignment marks, it is possible to use a variety of well-known methods which are used as methods for forming alignment marks in thin film transistors.

Specific examples thereof include the above-described methods for forming the gate electrode 14 and the like.

The number of the alignment marks 12 may be appropriately set depending on the size and the like of the substrate 10; however, basically, may be three or more. Meanwhile, in R to R methods described below, the size of the substrate 10 is the length and width of substrates.

When three or more alignment marks 12 are formed, it is possible to detect the positional deviation of the alignment marks 12, that is, the expansion and shrinkage of the substrate 10 in an x-y direction (biaxial direction), and thus it becomes possible to appropriately carry out an expansion and shrinkage control treatment described below.

Regarding the sizes, shapes, colors, and the like of the alignment marks 12, sizes and the like with which the alignment marks can be reliably detected when the expansion and shrinkage control treatment described below is carried out may be appropriately set depending on steps for manufacturing transistors being carried out, the forming materials of individual portions, and the like. That is, the alignment marks need to have shapes and sizes which enable the obtainment of positional accuracy necessary for transistors to be manufactured. In other words, the alignment marks need to have shapes and sizes which enables the obtainment of necessary accuracy which is calculated from positional accuracy (alignment accuracy) required in transistors to be manufactured.

Furthermore, regarding the mutual positional relationships such as the forming positions of the alignment marks 12 and intervals between the respective alignment marks 12, positions and the like in which the positional deviation of the alignment marks 12 can be preferably corrected by means of the expansion and shrinkage control treatment described below may be appropriately set depending on the sizes and the like of the substrate 10.

In the manufacturing of the transistor illustrated in FIGS. 1A to 2G, when the alignment marks 12 and the gate electrode 14 have been formed on the substrate 10, as schematically illustrated in FIG. 1B, a gate insulating film 16, that is, an insulator layer is formed so as to cover the substrate 10, the alignment marks 12, and the gate electrode 14.

As the forming materials of the gate insulating film 16 as well, similarly, it is possible to use a variety of well-known materials that are used as gate insulating films in thin film transistors.

Examples thereof include metallic oxides such as silicon oxide (SiOₓ), magnesium oxide, aluminum oxide, titanium oxide, germanium oxide, yttrium oxide, zirconium oxide, niobium oxide, and tantalum oxide, metallic nitrides such as silicon nitride (SiNₓ), metallic nitride oxides (metallic oxynitrides) such as silicon nitride oxide (SiOₓN_{y}), inorganic materials such as diamond-like carbon (DLC), a variety of polymer materials, laminate structures thereof, and the like.

In addition, as the methods for forming the gate insulating film 16, it is also possible to use a variety of well-known forming methods depending on materials.

Examples thereof include a variety of physical vapor deposition (PVD) methods such as sputtering, vacuum deposition, and ion plating, a variety of chemical vapor deposition (CVD) methods including the atomic layer deposition method (ALD method or ALE method), coating methods, printing methods, transfer methods, and the like.

Meanwhile, during the formation of the gate electrode 14, the alignment marks 12 formed on the substrate 10 may be used in order to determine the positions of formation devices. This fact can also be similarly applied to the formation of a semiconductor layer 24 or a resist layer 32 which will be described below.

When the gate insulating film 16 has been formed, patterns for the source electrode 18 and the drain electrode 20 are formed.

As the forming materials for the source electrode 18 and the drain electrode 20, it is possible to use a variety of well-known materials that are used in organic thin film transistors. Examples thereof include a variety of the above-described material exemplified for the gate electrode 14.

In addition, as the methods for forming patterns for the source electrode 18 and the drain electrode 20, it is also possible to use a variety of well-known methods depending on the forming materials. Examples thereof include a variety of the above-described methods exemplified for the gate electrode 14. In addition, it is also possible to form patterns for charge injection layers and the like and then form the source electrode 18 and the drain electrode 20 thereon. Meanwhile, the charge injection layers refer to hole injection layers in the case of p-type semiconductors and electron injection layers in the case of n-type semiconductors.

In the example illustrated in the drawings, the source electrode 18 and the drain electrode 20 are formed using a gas-phase film formation method and photolithography.

Meanwhile, even in a case in which the source electrode 18 and the drain electrode 20 are formed by means of film formation by gas-phase deposition using shadow masks, printing such as inkjet printing, or the like, it is preferable to carry out expansion and shrinkage control treatments such as temperature controls, humidity controls, or the like described below prior to the formation of patterns, preferably, again during the formation of patterns.

When the gate insulating film 16 has been formed as described above, as illustrated in FIG. 1C, a metal layer 30 which will serve as the source electrode 18 and the drain electrode 20 is formed so as to cover the gate insulating film 16. The metal layer 30 is formed using a gas-phase deposition method such as vacuum deposition.

Next, as illustrated in FIG. 1D, a resist layer 32 consisting of a photoresist is formed so as to cover the metal layer 30. The resist layer 32 may be formed using well-known methods for forming the resist layer 32 which are used to manufacture transistors such as methods in which solutions including photoresists which will serve as the resist layer 32 and the like are applied by means of spin coating or the like and then are post-baked.

When the resist layer 32 has been formed, the alignment marks 12 formed on the substrate 10 are detected, and an expansion and shrinkage control treatment for controlling the expansion and shrinkage of the substrate 10 is carried out.

For the detection of the alignment marks 12, it is possible to use a variety of methods used in the manufacturing of thin film transistors in which alignment marks are used such as methods in which imaging elements such as CCD sensors are used or methods in which microscopes are used as in aligners.

Meanwhile, the alignment marks 12 may be detected on the front surface, that is, the surface on which the transistor will be formed or on the rear surface.

In the example illustrated in the drawings, as an example, let us imagine that the substrate 10 has shrunk as schematically illustrated in FIG. 1D due to heating or humidification (changes in temperature or humidity) carried out in the above-described manufacturing steps and thus positional deviation of the alignment marks 12 is caused.

In order to deal with the above-described shrinkage, as schematically illustrated in FIG. 2E, before patterns are exposed using a photo mask 34, that is, patterns are formed (patterning), the substrate 10 on which the resist layer 32 is formed is placed on temperature adjustment means 40, the substrate 10 is heated so as to be expanded, and the alignment marks 12 on the substrate 10 and alignment marks 36 on the photo mask 34 are matched to each other.

Meanwhile, in a case in which the substrate 10 is in an expanded state, the alignment marks 12 on the substrate 10 and the alignment marks 36 on the photo mask 34 are matched to each other by cooling and shrinking the substrate 10.

Furthermore, as necessary, the positions and/or the angles of the substrate 10 and the photo mask 34 are matched to each other by moving the substrate 10 and/or the photo mask 34.

Next, exposure of the resist layer 32 is carried out through the photo mask 34 while maintaining the above-described heated state.

The alignment marks 36 on the photo mask 34 are formed so that the positions thereof in the surface direction during the exposure of the resist layer 32 match those of the alignment marks 12 formed on the substrate 10. Therefore, when the alignment marks 12 on the substrate 10 are matched to the alignment marks 36 on the photo mask 34 by means of heating, that is, when the positional deviation of the alignment marks 12 is improved, it is possible to improve the expansion and shrinkage of the substrate 10 and put the substrate back into the original state when the alignment marks 12 are formed.

Therefore, when the positions of the alignment marks 12 are improved by means of heating, it is possible to accurately expose patterns in the resist layer 32 in accordance with the formation positions of the source electrode 18 and the drain electrode 20 which are indicated by Reference Signal 32a. That is, it is possible to form the source electrode 18 and the drain electrode 20 at appropriate positions with respect to the gate electrode 14 without causing pattern deviation.

As described in Patent Document 1 or Patent Document 2, it is known that, in the manufacturing of transistors using film substrates, electrodes and the like are formed using alignment marks without causing pattern deviation.

In methods for manufacturing transistors of the related art in which alignment marks are used, patterns are reset depending on the detection results of alignment marks, and electrodes and the like are formed in accordance with the reset patterns, thereby preventing pattern deviation. However, in the above-described methods of the related art, since patterns are reset depending on the detection results of alignment marks, the manufacturing costs of transistors increase. In addition, methods in which patterns to be formed are reset depending on the detection results of alignment marks cannot be used in methods in which photo masks are used, or it is necessary to prepare a number of photo mask for a single pattern.

In contrast, in the manufacturing method of the present invention, expansion and shrinkage control treatments of the substrate 10 for expanding or shrinking the substrate 10 depending on the detection results of the alignment marks 12 formed on the substrate 10 are carried out, thereby improving the positional deviation of the alignment marks 12 and forming patterns. That is, the positional deviation of the alignment marks 12 is improved by expanding or shrinking the substrate 10 depending on the detection results of the alignment marks 12, whereby the substrate 10 is restored to the state when the alignment marks 12 are formed, and patterns are formed.

Therefore, according to the manufacturing method of the present invention, it is possible to not only form patterns for electrodes and the like without causing pattern deviation and but also reduce the manufacturing costs of transistors by removing the necessity for resetting patterns. In addition, according to the manufacturing method of the present invention, pattern exposure using photo masks can be carried out with a single photo mask.

In the example illustrated in the drawings, the substrate 10 is heated or cooled using the temperature adjustment means 40 depending on the detection results of the alignment marks 12, thereby improving the positional deviation of the alignment marks 12. That is, expansion and shrinkage control treatments are carried out by means of temperature controls.

Expansion and shrinkage control treatments by means of temperature controls are carried out using, for example, methods in which the relationship between the positional deviation degree of the alignment marks 12 and the linear expansion coefficient (thermal expansion coefficient) of the substrate 10 is ascertained, for example, tables (LUT) or calculation equations indicating the relationship between the positional deviation degree of the alignment marks 12 and heating temperatures/cooling temperatures for improving the positional deviation are prepared, and temperature controls of the substrate 10 are carried out using these tables or calculation equations.

Meanwhile, as described above, there is also another case in which the manufacturing method of the present invention is carried out after carrier substrates are attached to the substrate 10.

In this case, it is preferable that, in a state in which carrier substrates are attached (fixed) to the substrate 10, the linear expansion coefficient of the substrate 10 is ascertained, and tables or calculation equations indicating the relationship between the positional deviation degree of the alignment marks 12 and heating temperatures/cooling temperatures for improving the positional deviation are prepared.

Expansion and shrinkage control treatments by means of temperature controls may be carried out using these tables or calculation equations alone.

However, preferably, in a case in which the alignment marks 12 are redetected, and positional deviation of the alignment marks 12 is found in a state in which expansion and shrinkage control treatments by means of temperature controls have been carried out, it is preferable that, furthermore, temperatures are adjusted, the alignment marks are detected, the alignment marks 12 are confirmed to be at appropriate positions without any positional deviation, and then pattern exposure (pattern formation) is carried out.

In addition, in the example illustrated in the drawings, the positional deviation of the alignment marks 12 on the substrate 10 is improved by matching the alignment marks 12 on the substrate 10 to the alignment marks 36 on the photo mask 34.

However, in the present invention, the positional deviation of the alignment marks 12 on the substrate 10 may be improved using, in addition to the above-described method, methods in which the intervals between the respective alignment marks 12 are detected, and the temperature of the substrate 10 is controlled so as to obtain appropriate intervals, methods in which the positions of the respective alignment marks 12 such as the distances from the end portion of the substrate 10 are detected, and the temperature of the substrate 10 is controlled so that the positions of the respective alignment marks 12 become appropriate positions, methods in which the above-described methods are jointly used, or the like.

In the example illustrated in the drawings, as a preferred embodiment, exposure is carried out using the photo mask 34 in a state in which the substrate 10 is placed on the temperature adjustment means 40. In the present invention, the method of exposure is not limited thereto, and, when expansion and shrinkage control treatments have been carried out using the temperature adjustment means 40, it is also possible to remove the substrate 10 from the temperature adjustment means and carry out exposure using the photo mask 34.

However, as in the example illustrated in the drawings, when patterns are formed by carrying out pattern exposure using the photo mask 34 or the like, film formation by means of gas-phase deposition using shadow masks, or printing such as inkjet printing in a state in which temperature controls have been carried out, that is, substrate temperatures in expansion and shrinkage control treatments are maintained, it becomes possible to form patterns in a state in which the positional deviation of the alignment marks 12 is more appropriately removed.

Meanwhile, this fact can also be similarly applied to expansion and shrinkage control treatment by means of humidity controls which will be described below.

As the methods for controlling the temperature of the substrate 10 (methods for adjusting the temperature), it is possible to use a variety of methods such as methods in which heaters or hot plates are used, methods in which circulation of temperature adjustment media is used, methods in which Peltier elements are used, and well-known methods for controlling the temperatures of film-like articles (sheet-like articles).

Furthermore, as the methods for exposing patterns in the resist layer 32, it is possible to use, in addition to methods in which the photo mask 34 is used, a variety of well-known methods such as methods in which light beam scanning is used.

Treatments for improving the positional deviation of the alignment marks 12, that is, expansion and shrinkage control treatments for controlling the expansion and shrinkage of the substrate 10 carried out depending on the detection results of the alignment marks 12 are also preferably used for humidity controls of the substrate 10 in addition to the temperature controls as in the example illustrated in the drawings.

Meanwhile, in the manufacturing method of the present invention, subjects of the humidity controls are not only moisture but also solvents used in solutions and the like for forming the resist layer 32. Therefore, humidification and dehumidification of the substrate 10 may include controls of not only moisture but also the contents of solvents in the substrate 10.

As the methods for controlling the humidity, it is possible to use a variety of methods such as well-known methods for controlling the humidity of film-like articles (methods for adjusting the humidity).

Examples thereof include methods in which dry gas or wet gas (humidified gas) is blown toward the substrate 10, methods in which subjects are hold in high-humidity atmospheres or dry atmospheres, dehydration in vacuum environments, and the like. Meanwhile, in a case in which gas barrier films are used as the substrate 10, the blowing of gas needs to be carried out on a side opposite to gas barrier membranes (support side).

In any methods, humidity controls are carried out so as to dehumidify (dry) the substrate in a case in which the substrate 10 is shrunk and humidify the substrate in a case in which the substrate 10 is expanded.

Meanwhile, in the manufacturing method of the present invention, expansion and shrinkage control treatments may be carried out by carrying out both temperature controls and humidity controls.

Furthermore, as the methods for controlling expansion and shrinkage, in addition to temperature controls and humidity controls, it is also possible to use methods in which the positional deviation of the alignment marks 12 is improved by expanding the substrate 10 by means of pulling.

When patterns in the resist layer 32 have been exposed in the above-described manner, the resist layer 32 is developed, thereby leaving regions indicated by Reference Signal 32a and removing the resist layer 32. Next, the metal layer 30 is etched using the left resist layer 32 as masks, thereby forming the source electrode 18 and the drain electrode 20 as illustrated in FIG. 2F.

Here, in the example illustrated in the drawings, expansion and shrinkage control treatments for expanding and shrinking the substrate 10 by means of temperature controls are carried out depending on the detection results of the alignment marks 12 so as to improve the positional deviation of the alignment marks 12, and then patterns in the resist layer 32 are exposed. Therefore, it is possible to form the source electrode 18 and the drain electrode 20 without causing pattern deviation.

When the source electrode 18 and the drain electrode 20 have been formed, a semiconductor layer 24 is formed so as to cover the source electrode 18, the drain electrode 20, and the gate insulating film 16 as illustrated in FIG. 2G, thereby completing transistors. Alternatively, transistors may be completed by sealing the source electrode, the drain electrode, and the gate insulating film using sealing layers.

As the forming materials of the semiconductor layer 24, it is possible to use a variety of materials that are used for thin film transistors such as amorphous silicon, polycrystalline silicon, organic semiconductor materials, and oxide semiconductors.

Among these, from the viewpoint of weight reduction, cost reduction, softening, and the like, organic semiconductor materials such as pentacene derivatives such as 6,13-bis(triisopropyl-silylethynyl) pentacene (TIPS pentacene), anthradithiophene derivatives such as 5,11-bis(triethyl-silylethynyl) anthradithiophene (TES-ADT), benzothienobenzothiophene (BTBT) derivatives such as benzodithiophene (BDT) derivatives and dioctylbenzothienobenzothiophene (C8-BTBT), dinaphthothienothiophene (DNTT) derivatives, dinaphthobenzodithiophene (DNBDT) derivatives, 6,12-dioxaanthanthrene(perixanthenoxanthene) derivatives, naphthalenetetracarboxylic diimide (NTCDI) derivatives, perylene tetracarboxylic diimide (PTCDI) derivatives, polythiophene derivatives, poly(2,5-bis(thiophene-2-yl)thieno [3,2-b]thiophene) (PBTTT) derivatives, tetracyanoquinodimethane (TCNQ) derivatives, oligo-thiophenes, phthalocyanines, and fullerenes are preferably used.

As the methods for forming the semiconductor layer 24, it is also possible to use a variety of well-known methods that are used to form semiconductor layers in the manufacturing of thin film transistors such as coating methods, gas-phase deposition methods, combinations of these film formation methods and photolithography, and methods in which printing such as ink jet printing is carried out.

In the method illustrated in FIGS. 1A to 2G, in the manufacturing of bottom gate-bottom contact-type transistors, when the source electrode 18 and the drain electrode 20 are formed, that is, patterns in the resist layer 32 are exposed, treatments in which the alignment marks 12 are detected and the positional deviation of the alignment marks 12 is improved depending on the detection results thereof, that is, expansion and shrinkage control treatments for controlling the expansion and shrinkage of the substrate 10 are carried out.

However, in the present invention, in addition to the above-described case, in the manufacturing of not only the above-described bottom gate-bottom contact-type transistors but also a variety of transistors such as top gate-bottom contact-type transistors, bottom gate-top contact-type transistors, and top gate-bottom contact-type transistors, expansion and shrinkage control treatments in which the alignment marks 12 are detected and the expansion and shrinkage of the substrate 10 is controlled depending on the detection results thereof may be carried out during the formation of gate electrodes, during the formation of gate insulating films, during the formation of semiconductor layers, during the formation of source electrodes and drain electrodes, and the like.

Specifically, expansion and shrinkage control treatments are preferably carried out in steps in which patterns are formed in response to the formation of patterns.

Particularly, during the formation of patterns for source electrodes and drain electrodes in the manufacturing of bottom gate-type transistors or during the formation of patterns for gate electrodes in the manufacturing of top gate-type transistors, pattern deviation from patterns in upper layers or lower layers causes problems, and thus expansion and shrinkage control treatments are preferably carried out in response to steps in which the formation of highly accurate patterns is required.

Meanwhile, expansion and shrinkage control treatments may be carried out only once in the manufacturing of transistors, or expansion and shrinkage control treatments may be carried out multiple times in response to multiple steps such as the formation of gate electrodes, the formation of gate insulating films, the formation of semiconductor layers, and the formation of source electrodes and drain electrodes.

The example illustrated in FIGS. 1A to 2G is about the manufacturing of transistors by means of so-called batch methods, but the manufacturing method of the present invention can also be used to manufacture transistors by means of so-called roll to roll (R to R) methods.

As well known, R to R methods refer to manufacturing methods in which a long substrate (treatment subject) is sent out from a roll around which the substrate is coiled and is transported in the longitudinal direction, a coating composition is applied, dried, or the like, and the treated substrate is coiled in a roll shape.

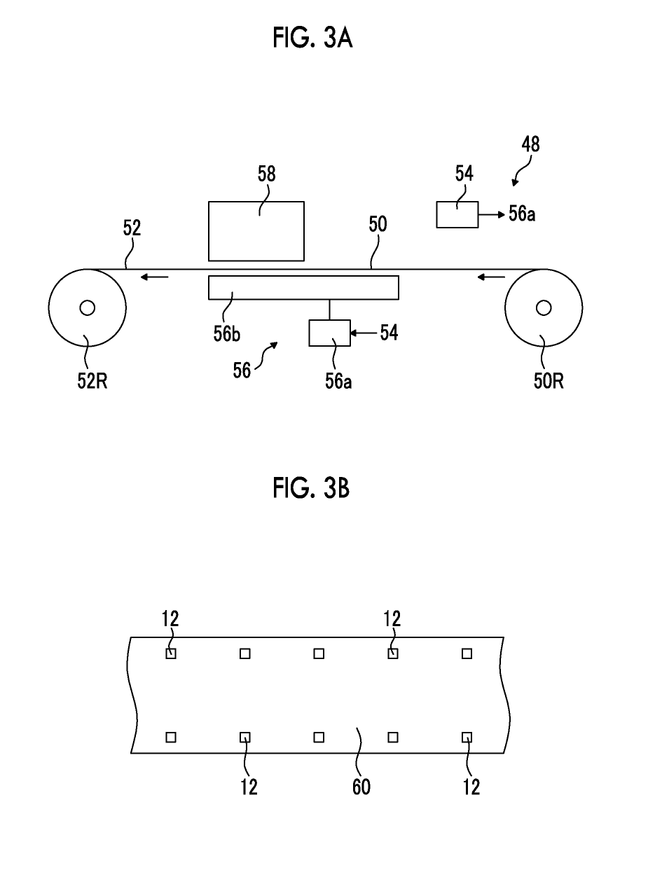

FIG. 3A conceptually illustrates an example of a manufacturing device by means of R to R with which the manufacturing method of the present invention is carried out.

In a manufacturing device 48 illustrated in FIG. 3A, a treatment subject material 50 is pulled out from a treatment subject material roll 50R formed by coiling the long treatment subject material 50 in a roll shape, patterns are formed while transporting the treatment subject material in the longitudinal direction, and a treated material 52 on which images are drawn is coiled in a roll shape so as to produce a treated material roll 52R.

The above-described manufacturing device 48 is basically constituted of a mark detection portion 54, an expansion and shrinkage control portion 56, and a pattern formation portion 58. Meanwhile, the manufacturing device 48 may have, in addition to the above-described members, a variety of members that well-known devices by means of R to R methods have such as transportation roller pairs or guide members for appropriately transporting the treatment subject material 50 and the like and a variety of sensors.

In the manufacturing device 48, examples of the treatment subject material 50 include articles obtained by forming the gate electrode 14 and the gate insulating film 16 on the substrate 10 which is illustrated in FIG. 1B and articles obtained by forming the gate electrode 14, the gate insulating film 16, the metal layer 30, and the resist layer 32 on the substrate 10 which is illustrated in FIG. 1D. Among these, treatment subject materials 50 obtained by forming patterns for the gate electrode 14 on a substrate 60 as illustrated in FIG. 3B or treatment subject materials 50 obtained by forming the gate insulating film 16 on the substrate are preferred. At this time, the gate insulating film 16 may be a patterned film or a non-patterned film.

In addition, as illustrated in FIG. 3B, on the substrate 60 in the treatment subject material 50, the alignment marks 12 are formed at equal intervals in the longitudinal direction near both end portions in the width direction at the same positions in the longitudinal direction. Meanwhile, this long substrate 60 is also preferably subjected to heat treatments prior to the manufacturing of transistors. Furthermore, for this long substrate 60 as well, the manufacturing of transistors may be carried out after carrier substrates are attached to the rear surface of the substrate.

In the manufacturing device 48 of FIG. 3, only improvement in the positional deviation of the alignment marks 12 and the formation of patterns are carried out. Meanwhile, the positional deviation of the alignment marks 12 is improved by means of temperature adjustment and/or humidity adjustment.

However, in a case in which the manufacturing method of the present invention is used in R to R methods, in addition to improvement in the positional deviation of the alignment marks and the formation of patterns, multiple steps including pattern formation or all the steps for manufacturing transistors may be carried out between a single time of sending of the treatment subject material 50 from the roll and the coiling of the treated treatment subject material 50 around the roll.

For example, between a single time of sending of the treatment subject material 50 from the roll and the coiling of the treated treatment subject material 50 around the roll, application of resist liquids, prebaking (the removal of solvents from the applied resist liquids by means of drying), improvement in the positional deviation of the alignment marks 12 (temperature/humidity adjustment), and the formation of patterns may be continuously carried out.

In the manufacturing device 48, the mark detection portion 54 is disposed on the downstream side of the treatment subject material roll 50R in the transportation direction of the treatment subject material 50. In the following description, the downstream side in the longitudinal direction of the treatment subject material 50 will also be simply referred to as the “downstream side”.

The mark detection portion 54 detects the alignment marks 12 formed on the substrate 60 in the treatment subject material 50 and sends detection results to a control portion 56a in the expansion and shrinkage control portion 56. As the methods for detecting the alignment marks 12 using the mark detection portion 54, it is possible to use a variety of well-known means, and the alignment marks 12 may be detected using, for example, imaging elements such as CCD sensors.

The expansion and shrinkage control portion 56 is disposed on the downstream side of the mark detection portion 54. The expansion and shrinkage control portion 56 is a portion for carrying out the above-described expansion and shrinkage control treatments for controlling the expansion and shrinkage of the substrate 60 and is constituted of the control portion 56a and temperature adjustment means 56b.

The control portion 56a is a portion for determining temperature adjustment carried out by the temperature adjustment means 56b from the detection results of alignment marks obtained using the mark detection portion 54.

That is, the control portion 56a stores the accurate positions of the alignment marks 12 formed on the substrate 60 and tables indicating the relationship between the above-described positional deviation degrees of the alignment marks 12 and heating temperatures/cooling temperatures for improving the positional deviation. Examples of the accurate positions of the alignment marks 12 formed on the substrate 60 include intervals between the alignment marks 12 in the width direction and the longitudinal direction and the like.

The control portion 56a detects the positional deviation degrees of the alignment marks 12 from the detection results of alignment marks obtained using the mark detection portion 54. Next, the control portion determines heating temperatures or cooling temperatures controlled using the temperature adjustment means 56b from the positional deviation degrees using tables and outputs commands to the temperature adjustment means 56b.

The temperature adjustment means 56b is well-known heating/cooling means and heats or cools the treatment subject material 50 (the substrate 60) in accordance with the heating temperatures or the cooling temperatures sent from the control portion 56a.

Meanwhile, temperature adjustment using the temperature adjustment means 56b may be carried out up to the upstream side of the pattern formation portion 58. However, in the manufacturing device 48 of the example illustrated in the drawings, as a preferred embodiment, the temperature adjustment (humidity adjustment) of the treatment subject material 50 is carried out using the temperature adjustment means 56b up to regions for forming patterns using the pattern formation portion 58.

Meanwhile, similar to the previous manufacturing of transistors by means of batch methods, the expansion and shrinkage control treatments using the manufacturing device 48 are not limited to temperature controls, and humidity controls can also be used.

In this case, the manufacturing device 48 is provided with gas-blowing means for blowing dry gas or humidified gas toward the treatment subject material 50 (the substrate 60) instead of the temperature adjustment means 56b. In addition, the control portion 56a stores tables indicating the relationship between the positional deviation degrees of the alignment marks 12 and humidification/dehumidification (drying) for improving the positional deviation.

The pattern formation portion 58 is a portion for forming patterns for manufacturing transistors using well-known means that is used to form a variety of patterns in the manufacturing of transistors.

For example, in a case in which the manufacturing device 48 is a device in which an article obtained by forming the gate electrode 14 and the gate insulating film 16 on the substrate 10 which is illustrated in FIG. 1B is used as the treatment subject material 50, as the pattern formation portion 58, ink jet printers having a nozzle row in the width direction (a direction orthogonal to the transportation direction) of the treatment subject material 50 which is intended to form patterns for the source electrode 18 and the drain electrode 20 are exemplified.

Alternatively, in a case in which the manufacturing device 48 is a device in which an article obtained by forming the gate electrode 14, the gate insulating film 16, the metal layer 30, and the resist layer 32 on the substrate 10 which is illustrated in FIG. 1D is used as the treatment subject material 50, as the pattern formation portion 58, light beam scanning devices for scanning light beams in the width direction of the treatment subject material 50 which is intended to exposure patterns in the resist layer 32 are exemplified.

In addition, in a case in which pattern exposure is carried out on the treatment subject material 50 (the resist layer 32 and the like), the pattern formation portion 58 may be an exposure device in which photo masks are used.

Meanwhile, in the manufacturing device 48, a second alignment detection portion may be further disposed in temperature control regions controlled using the temperature adjustment means 56b on the upstream side of the pattern formation portion 58, and temperature adjustment by the temperature adjustment means 56b may be amended from the detection results of the alignment marks 12 obtained using the second alignment detection portion.

Hereinafter, the actions of the manufacturing device 48 will be described.

In the manufacturing device 48, when the treatment subject material is pulled out from the treatment subject material roll 50R and is transported in the longitudinal direction, the mark detection portion 54 detects the alignment marks 12 formed on the substrate 60 and sends the detection results of the alignment marks 12 to the control portion 56a in the expansion and shrinkage control portion 56.

The control portion 56a detects the positional deviation of the alignment marks 12 from the detection results of the alignment marks, determines heating temperatures or cooling temperatures controlled using the temperature adjustment means 56b using the above-described tables, and outputs commands to the temperature adjustment means 56b.

The temperature adjustment means 56b heats or cools the treatment subject material 50 in accordance with the commands from the control portion 56a. Therefore, the substrate 60 is expanded or shrunk and is subjected to expansion and shrinkage control treatments, and the positional deviation of the alignment marks is improved. Furthermore, after the temperatures are adjusted, the positions and/or angles of inkjet heads or photo masks are adjusted as necessary, thereby matching the positions and/or angles of the treatment subject material 50 and the pattern formation portion 58.

The pattern formation portion 58 is transported in the longitudinal direction and forms patterns in the treatment subject material 50 having temperatures adjusted using the temperature adjustment means 56b. Here, the temperatures of the treatment subject material 50 is adjusted using the temperature adjustment means 56b, whereby the positional deviation of the alignment marks is improved. Therefore, the pattern formation portion 58 is capable of forming patterns at appropriate positions for the treatment subject material 50 without causing pattern deviation.

Next, the treated material 52 on which patterns are formed is coiled around the treated material roll 52R in a roll shape.

Hitherto, the method for manufacturing a transistor of the present invention has been described in detail, but the present invention is not limited to the above-described example, and it is needless to say that a variety of improvements or modification may be carried out within the scope of the gist of the present invention.

### EXAMPLES

Hereinafter, the method for manufacturing a transistor of the present invention will be described in more detail using specific examples of the present invention.

### Example 1 and Comparative Example 1

5 cm×5 cm gas barrier films were prepared as substrates.

These gas barrier films are the above-described organic-inorganic lamination-type gas barrier films in which a 100 μm-thick polyethylene naphthalate (PEN) film is used as a support, a 2 μm-thick organic layer consisting of acrylic polymers is provided on the surface, and a 30 nm-thick inorganic layer consisting of silicon nitride which is formed using a plasma CVD method is provided on the organic layer.

First, a heat treatment was carried out on the substrates at 150° C. for 24 hours. Next, a glass plate was attached as a carrier substrate to the rear surface (PEN film side) of the substrate on which the heat treatment had been carried out using a carrier film.

A 50 nm-thick gold thin film was formed on the surface of the substrate on the inorganic layer side by means of vacuum deposition.

A resist layer was formed on the gold thin film. The resist layer was formed using a spin coater.

The substrate on which the resist layer was formed was placed on the stage of a microscope. The stage of this microscope has a heating and cooling function. A glass mask having light-blocking portions that corresponded to alignment marks was superimposed on the substrate placed on the stage, and exposure using ultraviolet rays was carried out on the stage.

After the exposure, the substrate was removed from the stage of the microscope, and the resist on portions in which alignment marks would not be formed was removed by means of development. After that, etching was carried out so as to remove the gold thin film, and a substrate having gold alignment marks at four corners was produced.

The substrate produced in the above-described manner was left alone at room temperature for 24 hours.

After being left alone, the substrate was placed on the stage of the same microscope, a glass mask on which exposure had been carried out was superimposed, and the positional deviation degree of the alignment marks was measured using the microscope. As a result, the positional deviation of the alignment marks was 3 μm (Comparative Example 1).

Meanwhile, the positional deviation of alignment marks in the present examples refers to the average of the positional deviation degrees of three alignment marks when the remaining alignment mark on the substrate is superimposed on an alignment mark on the glass mask.

Next, the heating and cooling mechanism of the stage of the microscope was driven, thereby heating the substrate to 28° C. After the substrate was heated, the positional deviation degree of the alignment marks was measured in the same manner. As a result, the positional deviation of the alignment marks was smaller than 1 μm (Example 1).

### Example 2 and Comparative Example 2

Substrates having gold alignment marks at four corners were produced in the same manner as in Example 1.

These substrates were left alone for 30 minutes in an environment of 150° C. as a simulated process of a manufacturing step of transistors.

After being left alone, the positional deviation degree of the alignment marks was measured in the same manner as in Example 1. As a result, the positional deviation of the alignment marks was 10 μm (Comparative Example 2).

Next, the heating and cooling mechanism of the stage of the microscope was driven, thereby heating the substrate to 35° C. After the substrate was heated, the positional deviation degree of the alignment marks was measured in the same manner. As a result, the positional deviation of the alignment marks was smaller than 1 μm (Example 2).

### Example 3 and Comparative Example 3

Substrates having gold alignment marks at four corners were produced in the same manner as in Example 1.

These substrates were immersed in water for five minutes as a simulated process of a manufacturing step of transistors.

After being immersed, the positional deviation degree of the alignment marks was measured in the same manner as in Example 1. As a result, the positional deviation of the alignment marks was 6 μm (Comparative Example 3).

Next, the heating and cooling mechanism of the stage of the microscope was driven, thereby cooling the substrate to 20° C. After the substrate was cooled, the positional deviation degree of the alignment marks was measured in the same manner as in Example 1. As a result, the positional deviation of the alignment marks was smaller than 1 μm (Example 3).

### Example 4 and Comparative Example 4

Substrates having gold alignment marks at four corners were produced in the same manner as in Example 1.

These substrates were immersed in acetone for five minutes as a simulated process of a manufacturing step of transistors.

After being immersed, the positional deviation degree of the alignment marks was measured in the same manner as in Example 1. As a result, the positional deviation of the alignment marks was 5 μm (Comparative Example 4).

Next, the heating and cooling mechanism of the stage of the microscope was driven, thereby cooling the substrate to 20° C. After the substrate was cooled, the positional deviation degree of the alignment marks was measured in the same manner as in Example 1. As a result, the positional deviation of the alignment marks was smaller than 1 μm (Example 4).

### Examples 5 to 7

Substrates having gold alignment marks at four corners were produced in the same manner as in Example 1 except for the fact that

a 100 μm-thick polyimide (PI) film was used as the substrate instead of the gas barrier film (Example 5)

a 100 μm-thick PEN film was used as the substrate instead of the gas barrier film (Example 6), and

a 100 μm-thick polyethylene terephthalate (PET) film was used as the substrate instead of the gas barrier film (Example 7).

The respective substrates were left alone at room temperature for 24 hours in the same manner as in Example 1.

After being left alone, the substrates were placed on the stage of the same microscope, and the positional deviation degrees of the alignment marks were measured in the same manner as in Example 1. After the measurements, the heating and cooling mechanism of the stage of the microscope was driven, thereby

heating the substrate to 29° C. (Example 5),

heating the substrate to 27° C. (Example 6), and

cooling the substrate to 22° C. (Example 7).

After the temperatures of the substrates were adjusted, the positional deviation degrees of the alignment marks were measured in the same manner as in Example 1. As a result, the positional deviation degrees of the alignment marks were smaller than 1 μm in all the examples.

The results are summarized in Table 1 below.

TABLE 1

| | | | Temperature | Positional |
|---|---|---|---|---|
| | Substrate | Treatment | control | deviation |
| Example 1 | Gas barrier | Left alone for 24 | 28° C. | <1 μm |
| | | hours | | |
| Comparative | Gas barrier | Left alone for 24 | None | 3 μm |
| Example 1 | | hours | | |
| Example 2 | Gas barrier | 150° C. 30 min | 35° C. | <1 μm |
| Comparative | Gas barrier | 150° C. 30 min | None | 10 μm |
| Example 2 | | | | |
| Example 3 | Gas barrier | 5 min in water | 20° C. | <1 μm |
| Comparative | Gas barrier | 5 min in water | None | 6 μm |
| Example 3 | | | | |
| Example 4 | Gas barrier | 5 min in acetone | 21° C. | <1 μm |
| Comparative | Gas barrier | 5 min in acetone | None | 5 μm |
| Example 4 | | | | |
| Example 5 | PI | Left alone for 24 | 29° C. | <1 μm |
| | | hours | | |
| Example 6 | PEN | Left alone for 24 | 27° C. | <1 μm |
| | | hours | | |
| Example 7 | PET | Left alone for 24 | 22° C. | <1 μm |
| | | hours | | |

As shown in Table 1, in cases in which the film substrates were used, positional deviation of the alignment marks were caused due to the expansion and shrinkage of the substrates regardless of whether or not the simulated process was carried out. It can be considered from the linear expansion coefficients and hygroscopic expansion coefficients of the respective films that even changes in the temperature of 1° C. or the humidity of 1% RH cause positional deviation of the alignment marks.

In addition, according to the present invention in which expansion and shrinkage control treatments by means of the temperature controls of the substrate are carried out using the above-described characteristics, it is possible to improve the positional deviation of the alignment marks and thus manufacture transistors including no pattern deviation.

### Example 8 and Comparative Example 8

Substrates having gold alignment marks at four corners were produced in the same manner as in Example 1.

These substrates were left alone at room temperature for 24 hours in the same manner as in Example 1.

After being left alone, the positional deviation degree of the alignment marks was measured in the same manner as in Example 1. As a result, the positional deviation of the alignment marks was 3 μm (Comparative Example 8).

Next, the substrates were removed from the stage, and the glass plates used as the carrier substrates were peeled off.

After that, air wetted by water was blown toward the substrates for 30 seconds. Hereinafter, the air wetted by water will also be referred to as “humidified air”. The humidified air was blown from the PEN film side.

After the humidified air was blown, the positional deviation degree of the alignment marks was measured in the same manner as in Example 1. As a result, the positional deviation of the alignment marks was smaller than 1 μm (Example 8).

Meanwhile, in the present examples and Examples 9 to 14 below, the heating and cooling mechanism of the stage of the microscope was not driven.

### Example 9 and Comparative Example 9

Substrates having gold alignment marks at four corners were produced in the same manner as in Example 1.

These substrates were left alone for 30 minutes in an environment of 150° C. as a simulated process of a manufacturing step of transistors.

After being left alone, the positional deviation of the alignment marks was measured in the same manner as in Example 1. As a result, the positional deviation of the alignment marks was 10 μm (Comparative Example 9).

Next, the substrates were removed from the stage, and the glass plates used as the carrier substrates were peeled off.

After that, the humidified air was blown toward the substrates from the PEN film side for two minutes.

After the humidified air was blown, the positional deviation degree of the alignment marks was measured in the same manner as in Example 1. As a result, the positional deviation of the alignment marks was smaller than 1 μM (Example 9).

### Example 10 and Comparative Example 10

Substrates having gold alignment marks at four corners were produced in the same manner as in Example 1.

These substrates were immersed in water for five minutes as a simulated process of a manufacturing step of transistors.

After being immersed, the positional deviation of the alignment marks was measured in the same manner as in Example 1. As a result, the positional deviation of the alignment marks was 6 μm (Comparative Example 10).

Next, the substrates were removed from the stage, and the glass plates used as the carrier substrates were peeled off.

After that, the humidified air was blown toward the substrates from the PEN film side for one minute.

After the humidified air was blown, the positional deviation degree of the alignment marks was measured in the same manner as in Example 1. As a result, the positional deviation of the alignment marks was smaller than 1 μm (Example 10).

### Example 11 and Comparative Example 11

Substrates having gold alignment marks at four corners were produced in the same manner as in Example 1.

These substrates were immersed in acetone for five minutes as a simulated process of a manufacturing step of transistors.

After being immersed, the positional deviation of the alignment marks was measured in the same manner as in Example 1. As a result, the positional deviation of the alignment marks was 5 μm (Comparative Example 11).

Next, the substrates were removed from the stage, and the glass plates used as the carrier substrates were peeled off.

After that, the humidified air was blown toward the substrates from the PEN film side for one minute.

After the humidified air was blown, the positional deviation degree of the alignment marks was measured in the same manner as in Example 1. As a result, the positional deviation of the alignment marks was smaller than 1 μm (Example 11).

### Examples 12 to 14

Substrates having gold alignment marks at four corners were produced in the same manner as in Example 1 except for the fact that

a 100 μm-thick PI film was used as the substrate instead of the gas barrier film (Example 12)

a 100 μm-thick PEN film was used as the substrate instead of the gas barrier film (Example 13), and

a 100 μm-thick PET film was used as the substrate instead of the gas barrier film (Example 14).

The respective substrates were left alone at room temperature for 24 hours in the same manner as in Example 1.

After being left alone, the substrates were placed on the stage of the same microscope, and the positional deviation degrees of the alignment marks were measured in the same manner as in Example 1.

Next, the substrates were removed from the stage, and the glass plates used as the carrier substrates were peeled off.

After that,

humidified air was blown toward the substrate (Example 12),

humidified air was blown toward the substrate (Example 13), and

dry air was blown toward the substrate (Example 14),

respectively for 30 seconds.

After the humidified air was blown, the positional deviation degrees of the alignment marks were measured in the same manner as in Example 1. As a result, the positional deviation of the alignment marks was smaller than 1 μm in all the examples.

The results are summarized in Table 2 below.

TABLE 2

| | | | Humidity | Positional |
|---|---|---|---|---|
| | Substrate | Treatment | control | deviation |
| Example 8 | Gas barrier | Left alone for 24 | Humidified | <1 μm |
| | | hours | air | |
| Comparative | Gas barrier | Left alone for 24 | None | 3 μm |
| Example 8 | | hours | | |
| Example 9 | Gas barrier | 150° C. 30 min | Humidified | <1 μm |
| | | | air | |
| Comparative | Gas barrier | 150° C. 30 min | None | 10 μm |
| Example 9 | | | | |
| Example 10 | Gas barrier | 5 min in water | Dry air | <1 μm |
| Comparative | Gas barrier | 5 min in water | None | 6 μm |
| Example 10 | | | | |
| Example 11 | Gas barrier | 5 min in acetone | Dry air | <1 μm |
| Comparative | Gas barrier | 5 min in acetone | None | 5 μm |
| Example 11 | | | | |
| Example 12 | PI | Left alone for 24 | Humidified | <1 μm |
| | | hours | air | |
| Example 13 | PEN | Left alone for 24 | Humidified | <1 μm |
| | | hours | air | |
| Example 14 | PET | Left alone for 24 | Dry air | <1 μm |
| | | hours | | |

As shown in Table 2, even when the humidity of the substrates is controlled instead of the temperature controls of the substrates, the positional deviation of the alignment marks is improved, and thus transistors including no pattern deviation can be manufactured.

### Example 15

Sixteen bottom gate-bottom contact-type organic thin film transistors were produced on the same substrates 10 as in Example 1 using the method illustrated in FIGS. 1A to 2G. The same substrate 10 as in Example 1 is an organic-inorganic lamination-type gas barrier film in which a PEN film is used as a support, an organic layer is provided on the surface of the support, and an inorganic layer is provided on the organic layer as described above.

First, the same heat treatment as in Example 1 was carried out on the substrate 10, and a glass plate was attached as a carrier substrate to the rear surface.

A 50 nm-thick aluminum film was formed on the surface of the substrate on the inorganic layer side by means of vacuum deposition.

Next, a 10 μm-long gate electrode 14 was formed by means of photolithography in which photo masks were used. In addition, round alignment marks 12 were formed at the four corners of the substrate 10 at the same time as the formation of the gate electrode 14.

A propylene glycol monomethyl ether acetate (PGMEA) solution of a composition for gate insulting films was applied onto the substrate by means of spin coating and was baked for 60 minutes at 150° C., thereby forming a 400 nm-thick gate insulating film 16. In the composition for gate insulating films, the solution concentration of the PGMEA solution was set to 2% by mass using polyvinyl phenol/melamine having a mass ratio of 1/1.

Next, gold was vacuum-deposited on the gate insulating film 16, thereby forming a metal layer 30. Furthermore, a solution including a photoresist was applied onto the metal layer 30 by means of spin coating, thereby forming a resist layer 32.

Exposure of the resist layer 32 was carried out using a photo mask 34 having alignment marks 36 that corresponded to the alignment marks 12 formed on the substrate 10.

Meanwhile, prior to the exposure, the positional deviation of the alignment marks 12 on the substrate 10 was detected using the alignment marks 36 on the photo mask 34. Furthermore, the substrate 10 was heated to 36° C. prior to the exposure and during the exposure.

After the exposure, the resist layer 32 was developed so as to remove unnecessary parts of the resist, and then etching was carried out, thereby forming a source electrode 18 and a drain electrode 20 which had channel lengths of 5 μm and channel widths of 180 μm.

An organic semiconductor layer (TIPS-Pentacene) was formed on the source electrode 18, the drain electrode 20, and the gate insulating film 16 by means of spin coating so as to obtain a thickness of 100 nm. After that, the organic semiconductor layer was divided according to each element using a cutter, thereby producing semiconductor layers 24.

Furthermore, a composition for sealing layers (Cytop CTL-107MK, manufactured by AGC Chemicals Company) was applied onto the semiconductor layer 24 by means of spin coating and was baked at 140° C. for 20 minutes, thereby forming a 2 μm-thick sealing layer (the uppermost layer). As a result, sixteen organic thin film transistors were obtained.

### Example 16

Sixteen organic thin film transistors were produced in the same manner as in Example 15 except for the fact that, instead of the heating prior to and during the exposure of the resist layer 32 using the photo mask 34, the glass plate used as the carrier substrate was peeled off, humidified air was blown from the support (the PEN film side) for two minutes, then, exposure using the photo mask 34 was carried out, then, again, a glass substrate used as a carrier substrate was attached, and the subsequent steps were carried out.

### Comparative Example 12

Sixteen organic thin film transistors were produced in the same manner as in Example 15 except for the fact that the heating prior to and during the exposure of the resist layer 32 using the photo mask 34 was not carried out.

The respective electrodes in the organic thin film transistors produced in the above-described manner and individual terminals of a manual prober connected to a semiconductor parameter analyzer (4155C, manufactured by Agilent Technologies) were connected to each other, and field-effect transistors (FET) were evaluated.

As a result, in Examples 15 and 16, all of the sixteen organic thin film transistors appropriately operated.

In contrast, in Comparative Example 12, only four out of the sixteen organic thin film transistors appropriately operated.

In addition, sixteen organic thin film transistors were produced in the same manner as in Examples 15 and 16 and Comparative Example 12 except for the fact that C8-BTBT was used as the organic semiconductor instead of TIPS-Pentacene and no sealing layers were formed and were evaluated in the same manner.

As a result, in a case in which, instead of the exposure of the resist layer 32 using the photo mask 34, the same temperature control as in Example 15 was carried out and the same humidity control as in Example 16 was carried out, similarly, all of the sixteen organic thin film transistors appropriately operated.

In contrast, in a case in which no expansion and shrinkage control treatments were carried out as in Comparative Example 12, only four out of the sixteen organic thin film transistors appropriately operated.

From the above-described results, the effects of the present invention are clear.

The present invention can be preferably used to manufacture thin film transistors in which films are used as substrates.

### EXPLANATION OF REFERENCES

10, 60: substrate
12, 36: alignment mark
14: gate electrode
16: gate insulating film
18: source electrode
20: drain electrode
24: semiconductor layer
30: metal layer
32: resist layer
34: photo mask
48: manufacturing device
50: treatment subject material
52: treated material
54: mark detection portion
56: expansion and shrinkage control portion
56a: control portion
56b: temperature adjustment means
58: pattern formation portion

What is claimed is:

1. A method for manufacturing a transistor in which a film is used as a substrate, the method comprising:
using a substrate on which three or more alignment marks are formed; and
detecting the alignment marks and carrying out an expansion and shrinkage control treatment for controlling expansion and shrinkage of the substrate once or more by means of at least one of a temperature control of the substrate and a humidity control of the substrate depending on detection results of the alignment marks.

2. The method for manufacturing a transistor according to claim 1,
wherein the manufacturing of the transistor includes at least a step of forming a gate electrode, a step of forming a gate insulating film, a step of forming a semiconductor layer, and a step of forming a source electrode and a drain electrode, and
the expansion and shrinkage control treatment is carried out in the middle of or prior to at least one of the step of forming a gate electrode, the step of forming a gate insulating film, the step of forming a semiconductor layer, and the step of forming a source electrode and a drain electrode.

3. The method for manufacturing a transistor according to claim 1,
wherein a degree of deviation of the alignment marks is detected from the detection results of the alignment marks, and at least one of the temperature control of the substrate and the humidity control of the substrate is carried out on the basis of the degree of deviation of the alignment marks and at least one of a linear expansion coefficient and a hygroscopic expansion coefficient of the substrate.

4. The method for manufacturing a transistor according to claim 2,
wherein a degree of deviation of the alignment marks is detected from the detection results of the alignment marks, and at least one of the temperature control of the substrate and the humidity control of the substrate is carried out on the basis of the degree of deviation of the alignment marks and at least one of a linear expansion coefficient and a hygroscopic expansion coefficient of the substrate.

5. The method for manufacturing a transistor according to claim 3,
wherein the transistor is manufactured by fixing the substrate to a carrier, at least one of the linear expansion coefficient and hygroscopic expansion coefficient of the substrate is ascertained in a state in which the substrate is fixed to the carrier, and at least one of the temperature control of the substrate and the humidity control of the substrate is carried out using the ascertained information.

6. The method for manufacturing a transistor according to claim 4,
wherein the transistor is manufactured by fixing the substrate to a carrier, at least one of the linear expansion coefficient and hygroscopic expansion coefficient of the substrate is ascertained in a state in which the substrate is fixed to the carrier, and at least one of the temperature control of the substrate and the humidity control of the substrate is carried out using the ascertained information.

7. The method for manufacturing a transistor according to claim 1,
wherein, in a state in which at least one of the temperature and humidity of the substrate obtained by the expansion and shrinkage control treatment is maintained, pattern exposure in which a printing method or a photo mask is used is carried out, thereby carrying out pattern formation in the manufacturing of the transistor.

8. The method for manufacturing a transistor according to claim 2,
wherein, in a state in which at least one of the temperature and humidity of the substrate obtained by the expansion and shrinkage control treatment is maintained, pattern exposure in which a printing method or a photo mask is used is carried out, thereby carrying out pattern formation in the manufacturing of the transistor.

9. The method for manufacturing a transistor according to claim 3,
wherein, in a state in which at least one of the temperature and humidity of the substrate obtained by the expansion and shrinkage control treatment is maintained, pattern exposure in which a printing method or a photo mask is used is carried out, thereby carrying out pattern formation in the manufacturing of the transistor.

10. The method for manufacturing a transistor according to claim 4,
wherein, in a state in which at least one of the temperature and humidity of the substrate obtained by the expansion and shrinkage control treatment is maintained, pattern exposure in which a printing method or a photo mask is used is carried out, thereby carrying out pattern formation in the manufacturing of the transistor.

11. The method for manufacturing a transistor according to claim 5,
wherein, in a state in which at least one of the temperature and humidity of the substrate obtained by the expansion and shrinkage control treatment is maintained, pattern exposure in which a printing method or a photo mask is used is carried out, thereby carrying out pattern formation in the manufacturing of the transistor.

12. The method for manufacturing a transistor according to claim 6,
wherein, in a state in which at least one of the temperature and humidity of the substrate obtained by the expansion and shrinkage control treatment is maintained, pattern exposure in which a printing method or a photo mask is used is carried out, thereby carrying out pattern formation in the manufacturing of the transistor.

13. The method for manufacturing a transistor according to claim 1,
wherein the expansion and shrinkage control treatment is a humidity control, and the expansion and shrinkage control treatment is carried out by blowing gas having a controlled humidity toward the substrate.

14. The method for manufacturing a transistor according to claim 2,
wherein the expansion and shrinkage control treatment is a humidity control, and the expansion and shrinkage control treatment is carried out by blowing gas having a controlled humidity toward the substrate.

15. The method for manufacturing a transistor according to claim 1,
wherein the alignment marks are detected while transporting a long substrate in a longitudinal direction, the expansion and shrinkage control treatment is carried out on the downstream side of a detection position of the alignment marks, and pattern formation is carried out on the downstream side of the expansion and shrinkage control treatment in the manufacturing of the transistor.

16. The method for manufacturing a transistor according to claim 1,
wherein the substrate is a gas barrier film obtained by forming a gas barrier membrane on a support, and
the gas barrier membrane is obtained by alternately laminating one or more of organic layers and inorganic layers.

17. The method for manufacturing a transistor according to claim 16,
wherein the inorganic layer is a silicon nitride film.

18. The method for manufacturing a transistor according to claim 1, further comprising:
a step of forming an organic semiconductor layer.

19. The method for manufacturing a transistor according to claim 1,
wherein a heat treatment of the substrate is carried out prior to the expansion and shrinkage control treatment carried out for the first time.

20. The method for manufacturing a transistor according to claim 1,
wherein a step of forming the alignment marks is included, and the alignment marks are formed when patterning for a lowermost layer is carried out in the manufacturing of the transistor.
